(19) United States
(12) Patent Application Publication
(10) Pub. No.: US 2016/0118132 A1
(43) Pub. Date: Apr. 28, 2016

(54) Low Impact Read Disturb Handling

(71) Applicant: SanDisk Enterprise IP LLC, Milpitas, CA (US)

(72) Inventors: Taylor J. Prins, Milpitas, CA (US); Graeme M. Weston-Lewis, Pleasanton, CA (US)

(21) Appl. No.: 14/630,573

(22) Filed: Feb. 24, 2015

Related U.S. Application Data
(60) Provisional application No. 62/069,254, filed on Oct. 27, 2014.

(51) Int. Cl. G11C 16/34; G06F 12/02; G06F 11/07; G11C 16/26

(52) U.S. Cl. CPC G11C 16/3427; G11C 16/26; G11C 16/3431; G06F 12/0246; G06F 11/076; G06F 2212/7201

(57) ABSTRACT

A storage device system receives read commands from a host device and maintains a read disturb count for distinct zones of each of a plurality of non-volatile memory blocks in the storage device. The read disturb count for each zone corresponds to read operations performed in the zone and in predefined memory portions neighboring the zone. In accordance with a determination that the read disturb count for any zone satisfies predefined threshold criteria, the storage device performs a validation operation on one or more memory portions corresponding to that zone. If the validation operation is unsuccessful, the storage device resets the read disturb count for the zone and initiates a refresh operation on at least a portion of the corresponding block. If the validation operation is successful, the storage device resets the read disturb count for the zone that satisfied the predefined threshold criteria, and forgoes initiating the refresh operation.

### RELATED APPLICATIONS

This application claims priority to U.S. Provisional Application No. 62/069,254, filed Oct. 27, 2014, which is hereby incorporated by reference in its entirety.

### TECHNICAL FIELD

The disclosed embodiments relate generally to memory systems, and in particular, to reducing the impact of read disturbs on the operation of non-volatile memory in a storage device (e.g., comprising one or more flash memory devices).

### BACKGROUND

Semiconductor storage systems are commonly used for storing and managing data for electronic devices. A typical non-volatile data storage system stores data as an electrical value in the memory cells of the storage system and memory controllers are generally tasked with managing data transactions across multiple memory devices of the storage system.

It is well known that read operations on a word line can disturb data stored in neighboring word lines, and that data integrity can be compromised after a large number of read operations have been performed on neighboring word lines. Existing mechanisms for handling read disturbs tend to be overly conservative, designed to trigger garbage collection of blocks according to worst case “hot spot usage” assumptions, resulting in unnecessary garbage collection of non-volatile blocks and unnecessary write amplification when actual read operation patterns differ significantly from the worst case assumptions.

### SUMMARY

Various embodiments of systems, methods and devices within the scope of the appended claims each have several aspects, no single one of which is solely responsible for the attributes described herein. Without limiting the scope of the appended claims, after considering this disclosure, and particularly after considering the section entitled “Detailed Description” one will understand how the aspects of various embodiments are used to manage a storage system with a storage device including one or more memory devices. In one aspect, a storage controller of the storage device is configured to perform operations with/on the one or more memory devices (e.g., flash memory device(s)). In some embodiments, the storage controller maintains multiple read disturb counts for each non-volatile memory block in the storage system, one for each of several zones of the block, and furthermore avoids performing garbage collection on memory blocks due to read disturbs unless a memory validation operation on the block is unsuccessful. As a result, garbage collection operations due to read disturbs are significantly reduced, which reduces write amplification.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

FIG. 1 is a block diagram illustrating an implementation of a data storage system, in accordance with some embodiments.

FIG. 2 is a block diagram of an implementation of a management module, in accordance with some embodiments.

FIG. 3 is a block diagram of a set of read disturb counters and corresponding non-volatile memory block zones.

FIGS. 4A-4E illustrate a flowchart diagram of a method of managing a storage system, in accordance with some embodiments.

In accordance with common practice the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

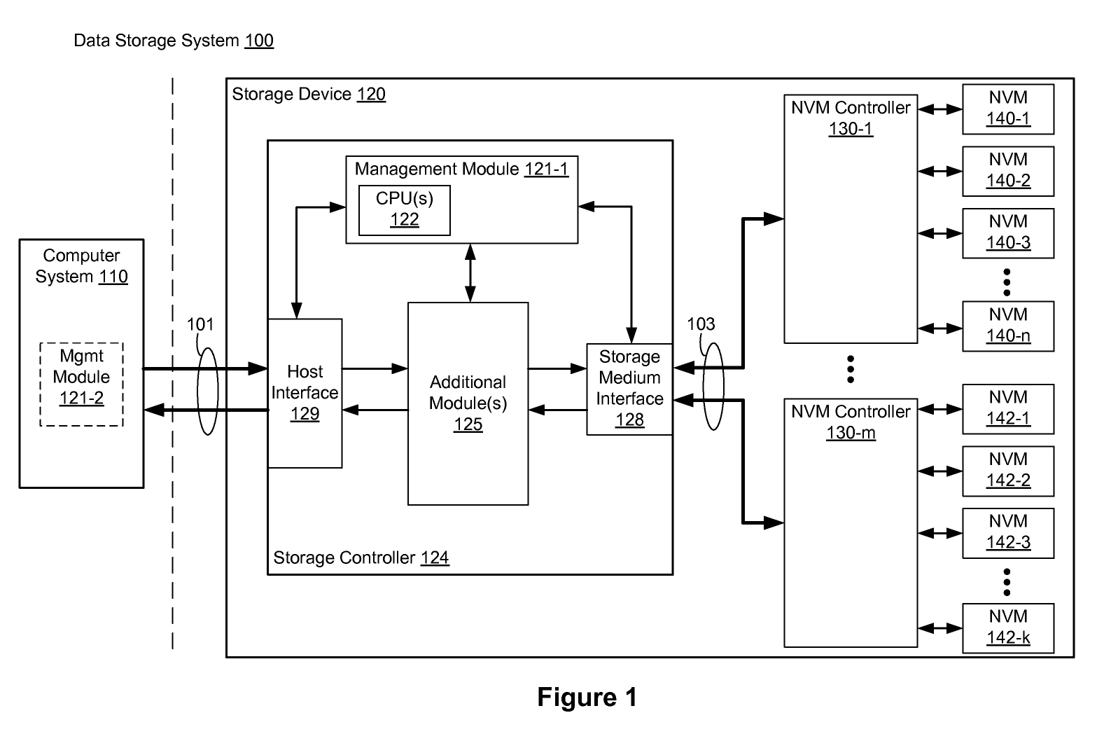

The various implementations described herein include systems, methods and/or devices that may limit the power consumed by a storage device with one or more memory devices (e.g., storage device 120 with non-volatile memory (NVM) devices 140, 142, FIG. 1).

(A1) More specifically, some embodiments include a method of managing a storage device that includes a plurality of non-volatile memory blocks. In some embodiments, the method includes receiving memory commands, including read commands, from one or more host devices. While processing the read commands, the storage device maintains a read disturb count for each of a plurality of distinct zones of each of the plurality of non-volatile memory blocks in the storage device, wherein the read disturb count for each zone of a respective memory block in the plurality of memory blocks corresponds to read operations performed on memory portions in the zone and read operations performed in one or more predefined memory portions neighboring the zone. In accordance with a determination that the read disturb count for any zone of the plurality of distinct zones of the plurality of non-volatile memory blocks in the storage device satisfies predefined threshold criteria (e.g., the read disturb count equals or exceeds a predefined maximum value), the storage device performs a validation operation on one or more memory portions corresponding to the zone that satisfied the predefined threshold criteria. In accordance with a determination that the validation operation was unsuccessful, the storage device resets the read disturb count for the zone that satisfied the predefined threshold criteria, and initiates a refresh operation on at least a portion of the non-volatile memory block that includes the zone that satisfied the predefined threshold criteria. In accordance with a determination that the validation operation was successful, the storage device resets the read disturb count for the zone that satisfied the predefined threshold criteria, and forgoes initiating the refresh operation.

(A2) In some embodiments of the method of A1, the method includes making a determination, each time the read disturb count for any zone of the plurality of distinct zones of the plurality of non-volatile memory blocks in the storage device is increased in response to the performance of a read operation, of whether the increased read disturb count satisfies the predefined threshold criteria.

(A3) In some embodiments of the method of any one of A1 and A2, the method includes increasing the read disturb count for a first zone of the plurality of distinct zones of the plurality of non-volatile memory blocks in the storage device in response to the performance of a read operation in the first zone, and increasing the read disturb count for the first zone in response to the performance of a read operation in any of the one or more predefined memory portions neighboring the first zone.

(A4) In some embodiments of the method of A3, for a predefined edge zone of each block of the plurality of non-volatile memory blocks in the storage device, increasing the read disturb count in response to the performance of a read operation in the predefined edge zone includes increasing the read disturb count by a first value when the read operation is performed in a first portion of the predefined edge zone and increasing the read disturb count by a second value, greater than the first value, when the read operation is performed in a second portion of the predefined edge zone.

(A5) In some embodiments of the method of any of A1 to A4, the read disturb count for any zone of the plurality of distinct zones of the plurality of non-volatile memory blocks in the storage device satisfies the predefined threshold criteria when the read disturb count for that zone reaches or exceeds a predefined maximum value.

(A6) In some embodiments of the method of A5, resetting the read disturb count for the zone that satisfied the predefined threshold criteria includes setting said read disturb count to a predefined reset value that is greater than a predefined initial value for the read disturb count.

(A7) In some embodiments of the method of A6, the predefined reset value is greater than the mathematical average of the predefined initial value and the predefined maximum value.

(A8) In some embodiments of the method of any of A1 to A7, the validation operation is performed by reading data stored in the one or more memory portions corresponding to the zone that satisfied the predefined threshold criteria, determining a corresponding bit error rate, and comparing the determined bit error rate with a threshold bit error rate; and furthermore the validation operation is successful when the determined bit error rate is less than the threshold bit error rate, and is unsuccessful when the determined bit error rate for the zone is greater than the threshold bit error rate.

(A9) In some embodiments of the method of A8, the one or more memory portions corresponding to the zone include a plurality of distinct memory portions, and determining the corresponding bit error rate includes determining a bit error rate for each of the plurality of distinct memory portions and selecting a worst bit error rate of the bit error rates for the plurality of distinct memory portions as the corresponding bit error rate.

(A10) In some embodiments of the method of any of A1 to A9, the method further includes periodically copying the read disturb counts for the plurality of distinct zones of the plurality of non-volatile memory blocks in the storage device from volatile storage to non-volatile storage in the storage device.

(A11) In some embodiments of the method of any of A1 to A10, each said read disturb count is stored using no more than 16 bits.

(A12) In some embodiments of the method of any of A1 to A11, initiating the refresh operation on at least a portion of the non-volatile memory block that includes the zone that satisfied the predefined threshold criteria includes initiating garbage collection of the entire non-volatile memory block that includes the zone that satisfied the predefined threshold criteria.

(A13) In some embodiments of the method of any of A1 to A11, the refresh operation is performed by copying to another non-volatile memory block all valid data in the zone that satisfied the predefined threshold criteria and invalidating all data in the zone. Valid data in other portions of the non-volatile memory block that includes the zone that satisfied the predefined threshold criteria are not refreshed in response to the determination that the validation operation was unsuccessful.

(A14) In another aspect, a storage device includes non-volatile memory, including a plurality of non-volatile memory blocks, and one or more storage controllers having one or more processors configured to execute instructions in one or more programs, wherein the one or more storage controllers are configured to perform or control performance of any of the methods A1 to A13 described herein.

(A15) In some embodiments of the storage device of A14, the one or more storage controllers include a read disturb module for maintaining the read disturb count for each of the plurality of distinct zones of each of the plurality of non-volatile memory blocks in the storage device, performing the validation operation, and initiating the refresh operation in accordance with a determination that the validation operation was unsuccessful.

(A16) In yet another aspect, any of the methods A1 to A13 described above are performed by a storage device including means for performing or controlling performance of any of the methods described herein.

(A17) In yet another aspect, some embodiments include a non-transitory computer readable storage medium, storing one or more programs configured for execution by one or more processors of a storage device, the one or more programs including instructions for performing or controlling performance of any of the methods A1 to A13 described herein.

FIG. 1 is a block diagram illustrating data storage system 100, in accordance with some embodiments. While some example features are illustrated, various other features have not been illustrated for the sake of brevity and so as not to obscure pertinent aspects of the example embodiments disclosed herein. To that end, as a non-limiting example, data storage system 100 includes storage device 120 (also sometimes called an information storage device, or a data storage device, or a memory device), which includes storage controller 124, and non-volatile memory (e.g., one or more NVM device(s) 140, 142 such as one or more flash memory devices), and is used in conjunction with computer system 110. In some embodiments, storage device includes one or more non-volatile memory (NVM) controllers 130 such as flash controllers, while in other embodiments storage controller 124 is an NVM controller, and the functions described below as being performed by the one or more NVM controllers 130 are instead performed by storage controller 124.

In some embodiments, storage device 120 includes a single NVM device while in other embodiments storage device 120 includes a plurality of NVM devices. In some embodiments, NVM devices 140, 142 include NAND-type flash memory or NOR-type flash memory. Further, in some embodiments, NVM controllers 130 and/or storage controller 124 are solid-state drive (SSD) controllers. However, other types of storage media may be included in accordance with aspects of a wide variety of embodiments (e.g., PCRAM, ReRAM, STT-RAM, etc.). In some embodiments, a flash memory device includes one or more flash memory die, one or more flash memory packages, one or more flash memory channels or the like. In some embodiments, data storage system 100 can contain one or more storage device 120s.

Computer system 110 is coupled to storage controller 124 through data connections 101. However, in some embodiments computer system 110 includes storage controller 124, or a portion of storage controller 124, as a component and/or a subsystem. For example, in some embodiments, some or all of the functionality of storage controller 124 is implemented by software executed on computer system 110. Computer system 110 may be any suitable computer device, such as a computer, a laptop computer, a tablet device, a netbook, an internet kiosk, a personal digital assistant, a mobile phone, a smart phone, a gaming device, a computer server, or any other computing device. Computer system 110 is sometimes called a host, host system, client, or client system. In some embodiments, computer system 110 is a server system, such as a server system in a data center. In some embodiments, computer system 110 includes one or more processors, one or more types of memory, a display and/or other user interface components such as a keyboard, a touch screen display, a mouse, a track-pad, a digital camera, and/or any number of supplemental devices to add functionality. In some embodiments, computer system 110 does not have a display and other user interface components.

The one or more NVM controllers 130 are coupled with storage controller 124 through connections 103. Connections 103 are sometimes called data connections, but typically convey commands in addition to data, and optionally convey metadata, error correction information and/or other information in addition to data values to be stored in NVM devices 140, 142 and data values read from NVM devices 140, 142. In embodiments lacking NVM controllers 130, in which storage controller 124 is an NVM controller, connections 103 convey commands and data between storage controller 124 and NVM devices 140, 142.

In some embodiments, however, storage controller 124, the one or more NVM controllers 130 (if provided), and NVM devices 140, 142 are included in the same device (i.e., an integrated device) as components thereof. Furthermore, in some embodiments, storage device 120 (e.g., including storage controller 124, the one or more NVM controllers 130, and NVM devices 140, 142) is embedded in a host device (e.g., computer system 110), such as a mobile device, tablet, other computer or computer controlled device, and the methods described herein are performed, at least in part, by the embedded storage controller.

In some embodiments, storage device 120 includes NVM devices 140, 142 such as flash memory devices (e.g., NVM devices 140-1 through 140-n, and NVM devices 142-1 through 142-k) and NVM controllers 130 (e.g., NVM controllers 130-1 through 130-m). Viewed another way, storage device 120 includes m memory channels, each of which has a set of NVM devices 140 or 142 that are optionally coupled to a corresponding NVM controller 130, where m is an integer greater than one. However, in some embodiments, two or more memory channels share an NVM controller 130. In either example, each memory channel has its own distinct set of NVM devices 140 or 142. In a non-limiting example, the number of memory channels in a typical storage device is 8, 16, or 32. In another non-limiting example, the number of NVM devices 140 or 142 per memory channel is typically 8, 16, 32, or 64. Furthermore, in some embodiments, the number of NVM devices 140/142 is different in different memory channels.

In some embodiments, each NVM controller of NVM controllers 130 include one or more processing units (also sometimes called CPUs or processors or microprocessors or microcontrollers) configured to execute instructions in one or more programs (e.g., in NVM controllers 130). In some embodiments, the one or more processors are shared by one or more components within, and in some cases, beyond the function of NVM controllers 130. NVM devices 140, 142 are coupled to NVM controllers 130 through connections that typically convey commands in addition to data, and optionally convey metadata, error correction information and/or other information in addition to data values to be stored in NVM devices 140, 142 and data values read from NVM devices 140, 142. NVM devices 140, 142 may include any number (i.e., one or more) of memory devices including, without limitation, non-volatile semiconductor memory devices, such as flash memory device(s).

For example, flash memory device(s) (e.g., NVM devices 140, 142) can be configured for enterprise storage suitable for applications such as cloud computing, for database applications, primary and/or secondary storage, or for caching data stored (or to be stored) in secondary storage, such as hard disk drives. Additionally and/or alternatively, flash memory device(s) (e.g., NVM devices 140, 142) can also be configured for relatively smaller-scale applications such as personal flash drives or hard-disk replacements for personal, laptop, and tablet computers. Although flash memory devices and flash controllers are used as an example here, in some embodiments storage device 120 includes other non-volatile memory device(s) and corresponding non-volatile storage controller(s).

In some embodiments, NVM devices 140, 142 are divided into a number of addressable and individually selectable blocks. In some embodiments, the individually selectable blocks are the minimum size erasable units in a flash memory device. In other words, each block contains the minimum number of memory cells that can be erased simultaneously. Each block is usually further divided into a plurality of pages and/or word lines, where each page or word line is typically an instance of the smallest individually accessible (readable) portion in a block. In some embodiments (e.g., using some types of flash memory), the smallest individually accessible unit of a data set, however, is a sector or codeword, which is a subunit of a page. That is, a block includes a plurality of pages, each page contains a plurality of sectors or codewords, and each sector or codeword is the minimum unit of data for reading data from the flash memory device.

In some embodiments, storage controller 124 includes a management module 121-1, a host interface 129, a storage medium (I/O) interface 128, and additional module(s) 125. Storage controller 124 may include various additional features that have not been illustrated for the sake of brevity and so as not to obscure pertinent features of the example embodiments disclosed herein, and a different arrangement of features may be possible.

Host interface 129 provides an interface to computer system 110 through data connections 101. Similarly, storage medium interface 128 provides an interface to NVM controllers 130 though connections 103. In some embodiments, storage medium interface 128 includes read and write circuitry, including circuitry capable of providing reading signals to NVM controllers 130 (e.g., reading threshold voltages for NAND-type flash memory). In some embodiments, connections 101 and connections 103 are implemented as a communication media over which commands and data are communicated, using a protocol such as DDR3, SCSI, SATA, SAS, or the like. In some embodiments, storage controller 124 includes one or more processing units (also sometimes called CPUs or processors or microprocessors or microcontrollers) configured to execute instructions in one or more programs (e.g., in storage controller 124). In some embodiments, the one or more processors are shared by one or more components within, and in some cases, beyond the function of storage controller 124.

In some embodiments, management module 121-1 includes one or more processing units 122 (CPUs, also sometimes called processors or microprocessors or microcontrollers) configured to execute instructions in one or more programs (e.g., in management module 121-1). In some embodiments, the one or more CPUs 122 are shared by one or more components within, and in some cases, beyond the function of storage controller 124. Management module 121-1 is coupled to host interface 129, additional module(s) 125 and storage medium interface 128 in order to coordinate the operation of these components. In some embodiments, one or more modules of management module 121-1 are implemented in management module 121-2 of computer system 110. In some embodiments, one or more processors of computer system 110 (not shown) are configured to execute instructions in one or more programs (e.g., in management module 121-2). In some embodiments, management module 121-2 is coupled to storage device 120 in order to manage the operation of storage device 120.

Additional module(s) 125 are coupled to storage medium interface 128, host interface 129, and management module 121-1. As an example, additional module(s) 125 may include an error control module to limit the number of uncorrectable errors inadvertently introduced into data during writes to memory and/or reads from memory. In some embodiments, additional module(s) 125 are executed in software by the one or more CPUs 122 of management module 121-1, and, in other embodiments, additional module(s) 125 are implemented in whole or in part using special purpose circuitry (e.g., to perform encoding and decoding functions). In some embodiments, additional module(s) 125 are implemented in whole or in part by software executed on computer system 110.

In some embodiments, an error control module, included in additional module(s) 125, includes an encoder and a decoder. In some embodiments, the encoder encodes data by applying an error-correcting code (ECC) to produce a codeword, which is subsequently stored in NVM devices 140, 142. When encoded data (e.g., one or more codewords) is read from NVM devices 140, 142, the decoder applies a decoding process to the encoded data to recover the data, and to correct errors in the recovered data within the error correcting capability of the error-correcting code. Those skilled in the art will appreciate that various error-correcting codes have different error detection and correction capacities, and that particular codes are selected for various applications for reasons beyond the scope of this disclosure. As such, an exhaustive review of the various types of error-correcting codes is not provided herein. Moreover, those skilled in the art will appreciate that each type or family of error-correcting codes may have encoding and decoding algorithms that are particular to the type or family of error-correcting codes. On the other hand, some algorithms may be utilized at least to some extent in the decoding of a number of different types or families of error-correcting codes. As such, for the sake of brevity, an exhaustive description of the various types of encoding and decoding algorithms generally available and known to those skilled in the art is not provided herein.

In some embodiments, during a write operation, host interface 129 receives data to be stored in NVM devices 140, 142 from computer system 110. The data received by host interface 129 is made available to an encoder (e.g., in additional module(s) 125), which encodes the data to produce one or more codewords. The one or more codewords are made available to storage medium interface 128, which transfers the one or more codewords to NVM devices 140, 142 (e.g., through NVM controllers 130) in a manner dependent on the type of storage medium being utilized.

In some embodiments, a read operation is initiated when computer system (host) 110 sends one or more host read commands (e.g., via data connections 101, or alternatively a separate control line or bus) to storage controller 124 requesting data from NVM devices 140, 142. Storage controller 124 sends one or more read access commands to NVM devices 140, 142 (e.g., through NVM controllers 130), via storage medium interface 128, to obtain raw read data in accordance with memory locations (addresses) specified by the one or more host read commands. Storage medium interface 128 provides the raw read data (e.g., comprising one or more codewords) to a decoder (e.g., in additional module(s) 125). If the decoding is successful, the decoded data is provided to host interface 129, where the decoded data is made available to computer system 110. In some embodiments, if the decoding is not successful, storage controller 124 may resort to a number of remedial actions or provide an indication of an irresolvable error condition.

As explained above, a storage medium (e.g., NVM devices 140, 142) is divided into a number of addressable and individually selectable blocks and each block is optionally (but typically) further divided into a plurality of pages and/or word lines and/or sectors. While erasure of a storage medium is performed on a block basis, in many embodiments, reading and programming of the storage medium is performed on a smaller subunit of a block (e.g., on a page basis, word line basis, or sector basis). In some embodiments, the smaller subunit of a block consists of multiple memory cells (e.g., single-level cells or multi-level cells). In some embodiments, programming is performed on an entire page. In some embodiments, a multi-level cell (MLC) NAND flash typically has four possible states per cell, yielding two bits of information per cell. Further, in some embodiments, a MLC NAND has two page types: (1) a lower page (sometimes called fast page), and (2) an upper page (sometimes called slow page). In some embodiments, a triple-level cell (TLC) NAND flash has eight possible states per cell, yielding three bits of information per cell. Although the description herein uses TLC, MLC, and SLC as examples, those skilled in the art will appreciate that the embodiments described herein may be extended to memory cells that have more than eight possible states per cell, yielding more than three bits of information per cell. In some embodiments, the encoding format of the storage media (i.e., TLC, MLC, or SLC and/or a chosen data redundancy mechanism or ECC code) is a choice made when data is actually written to the storage media.

As an example, if data is written to a storage medium in pages, but the storage medium is erased in blocks, pages in the storage medium may contain invalid (e.g., stale) data, but those pages cannot be overwritten until the whole block containing those pages is erased. In order to write to the pages with invalid data, the pages (if any) with valid data in that block are read and re-written to a new block and the old block is erased (or put on a queue for erasing). This process is called garbage collection. After garbage collection, the new block contains the pages with valid data and may have free pages that are available for new data to be written, and the old block can be erased so as to be available for new data to be written. Since flash memory can only be programmed and erased a limited number of times, the efficiency of the algorithm used to pick the next block(s) to re-write and erase has a significant impact on the lifetime and reliability of flash-based storage systems.

Write amplification is a phenomenon where the actual amount of physical data written to a storage medium (e.g., NVM devices 140, 142 in storage device 120) is a multiple of the logical amount of data written by a host (e.g., computer system 110, sometimes called a host) to the storage medium. As discussed above, when a block of storage medium must be erased before it can be re-written, the garbage collection process to perform these operations results in re-writing data one or more times. This multiplying effect increases the number of writes required over the life of a storage medium, which shortens the time it can reliably operate. The formula to calculate the write amplification of a storage system is given by equation:

$$\frac{amount of data written to a storage medium}{amount of data written by a host}$$

One of the goals of any flash memory based data storage system architecture is to reduce write amplification as much as possible so that available endurance is used to meet storage medium reliability and warranty specifications. Higher system endurance also results in lower cost as the storage system may need less over-provisioning. By reducing write amplification, the endurance of the storage medium is increased and the overall cost of the storage system is decreased. Generally, garbage collection is performed on erase blocks with the fewest number of valid pages for best performance and best write amplification.

Flash memory devices utilize memory cells to store data as electrical values, such as electrical charges or voltages. Each flash memory cell typically includes a single transistor with a floating gate that is used to store a charge, which modifies the threshold voltage of the transistor (i.e., the voltage needed to turn the transistor on). The magnitude of the charge, and the corresponding threshold voltage the charge creates, is used to represent one or more data values. In some embodiments, during a read operation, a reading threshold voltage is applied to the control gate of the transistor and the resulting sensed current or voltage is mapped to a data value.

The terms “cell voltage” and “memory cell voltage,” in the context of flash memory cells, means the threshold voltage of the memory cell, which is the minimum voltage that needs to be applied to the gate of the memory cell's transistor in order for the transistor to conduct current. Similarly, reading threshold voltages (sometimes also called reading signals and reading voltages) applied to a flash memory cells are gate voltages applied to the gates of the flash memory cells to determine whether the memory cells conduct current at that gate voltage. In some embodiments, when a flash memory cell's transistor conducts current at a given reading threshold voltage, indicating that the cell voltage is less than the reading threshold voltage, the raw data value for that read operation is a “1” and otherwise the raw data value is a “0.”

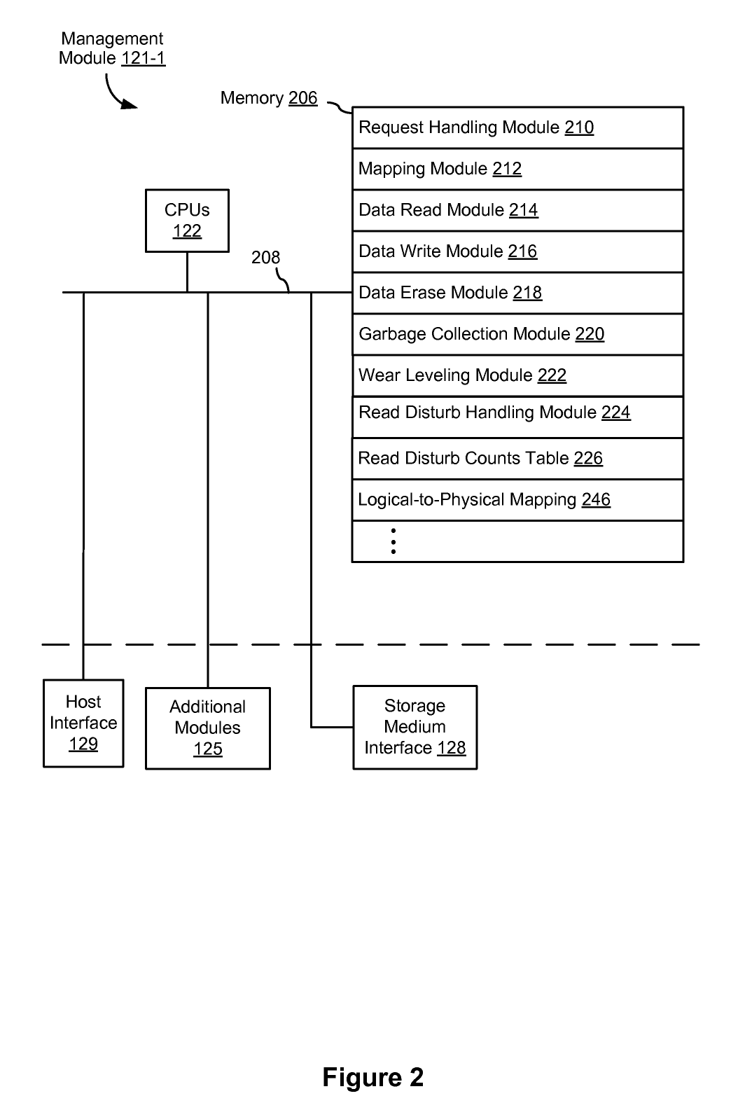

FIG. 2 is a block diagram illustrating a management module 121-1, in accordance with some embodiments, as shown in FIG. 1. Management module 121-1 typically includes one or more processing units (sometimes called CPUs or processors) 122 for executing modules, programs, and/or instructions stored in memory 206 and thereby performing processing operations, memory 206 (sometimes called controller memory), and one or more communication buses 208 for interconnecting these components. The one or more communication buses 208 optionally include circuitry (sometimes called a chipset) that interconnects and controls communications between system components. Management module 121-1 is coupled to host interface 129, additional module(s) 125, and storage medium interface 128 by the one or more communication buses 208. Memory 206 includes high-speed random access memory, such as DRAM, SRAM, DDR RAM, or other random access solid state memory devices, and may include non-volatile memory, such as one or more magnetic disk storage devices, optical disk storage devices, flash memory devices, or other non-volatile solid state storage devices. Memory 206 optionally includes one or more storage devices remotely located from CPU(s) 122. Memory 206, or alternatively the non-volatile memory device(s) within memory 206, comprises a non-transitory computer readable storage medium. In some embodiments, memory 206, or the non-transitory computer readable storage medium of memory 206 stores the following programs, modules, and data structures, or a subset or superset thereof:
request handling module 210 for receiving input/output (I/O) requests from a host (e.g., write requests and/or read requests);
mapping module 212 for mapping logical addresses to physical addresses using logical-to-physical mapping 242;
data read module 214 data for reading data, or causing data to be read, from storage device 120 (e.g., NVM devices 140, 142);
data write module 216 writing data, or causing data to be written, to storage device 120 (e.g., NVM devices 140, 142);
data erase module 218 for erasing data, or causing data to be erased, from storage device 120 (e.g., NVM devices 140, 142);
garbage collection module 220 for performing a garbage collection process on one or more memory portions (i.e., blocks) of storage device 120 (e.g., NVM devices 140, 142);
wear leveling module 222 for optimally determining memory portions (i.e., pages or blocks) of storage device 120 (e.g., NVM devices 140, 142) for storing data so as to evenly wear the memory portions of storage device 120 (e.g., NVM devices 140, 142);
read disturb handling module 224 for maintaining a running counting of read disturbs in each zone of a plurality of non-volatile memory blocks, performing a validation operation when any read disturb count satisfies predefined threshold criteria, and initiating a data refresh when the validation operation is unsuccessful;
read disturb counts table 226, for storing the read disturb counts maintained by read disturb handling module 224; and
logical-to-physical mapping 246 storing a logical-to-physical map (used, for example, by mapping module 212), which maps logical addresses recognized by the host (e.g., computer system 110, FIG. 1) to physical addresses of storage device 120 (e.g., NVM devices 140, 142).

Each of the above identified elements may be stored in one or more of the previously mentioned memory devices, and corresponds to a set of instructions for performing a function described above. The above identified modules or programs (i.e., sets of instructions) need not be implemented as separate software programs, procedures or modules, and thus various subsets of these modules may be combined or otherwise re-arranged in various embodiments. In some embodiments, memory 206 may store a subset of the modules and data structures identified above. Furthermore, memory 206 may store additional modules and data structures not described above. In some embodiments, the programs, modules, and data structures stored in memory 206, or the non-transitory computer readable storage medium of memory 206, provide instructions for implementing some of the methods described below. In some embodiments, some or all of these modules may be implemented with specialized hardware circuits that subsume part or all of the module functionality.

Although FIG. 2 shows a management module 121-1, FIG. 2 is intended more as functional description of the various features which may be present in a management module than as a structural schematic of the embodiments described herein. In practice, and as recognized by those of ordinary skill in the art, items shown separately could be combined and some items could be separated. In some embodiments, one or more of the operations and/or modules of management module 121-1 may instead be performed and/or implemented by management module 121-2. In some embodiments, one or more of the operations and/or modules of management module 121-1 may instead be performed and/or implemented by NVM controllers 130. For example, each NVM controller includes power throttling logic (e.g., similar to power throttling module 224, FIG. 2) for limiting the power consumption of corresponding NVM devices. In some embodiments, power throttling module 224 may be implemented in whole or in part by software, hardware, firmware, or any combination thereof in data storage system 100 (FIG. 1).

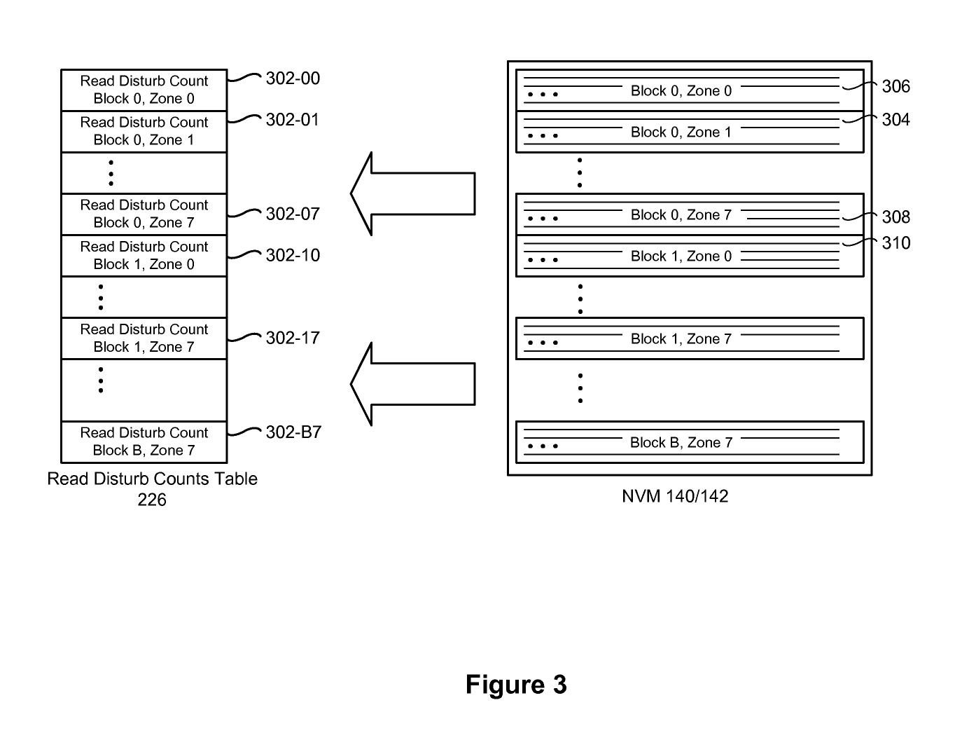

FIG. 3 is a block diagram of a read disturb counts table 226, which stores read disturb counts 302, and corresponding non-volatile memory block zones. More particularly, FIG. 3 shows that non-volatile memory 140, 142 of storage device 120 (FIG. 1) includes a plurality of non-volatile memory blocks 0 through B. In this example, each block in the plurality of blocks has been divided into eight zones, zone 0 through zone 7, each of which has a distinct set of word lines. In one example, each block in the plurality of blocks has 128 word lines, each of which is used to store one or more pages of data, and thus each of the eight zones of the block has 16 word lines. Each block has two edge zones, zone 0 and zone 7. Zone 0 includes word lines 0 to 15 and zone 7 includes word lines to 112 to 127. In some embodiments, read operations on word line 1 (306) and word line 126 (308), in zones 0 and 7, respectively, are known to cause a greater degree of data degradation on neighboring word lines than read operations on any of the other word lines (e.g., word lines 0, 2-125 and 127).

Furthermore, in some embodiments, read operations on the first and last word lines in each zone of a block (excluding blocks at the physical edge of a memory array in a die) are known to cause read disturb effects on data stored in neighboring word lines on both sides of those word lines. Stated another way, a read operation on a first word line at a predefined physical edge of a zone (i.e., a zone of the plurality of zones in a block of the plurality of non-volatile memory blocks) causes read disturb effects on data stored in both that zone and also in a neighboring zone. Depending on the location of the zone in the block, the neighboring zone is either in the same block, or in a neighboring block. For example, with reference to FIG. 3, when a read operation is performed on word line 310, in zone 0 of block 1, which is at the edge of block 1, zone 0 that neighbors zone 7 of block 0, the read disturb handling module increments the read disturb count 302-10 for block 1, zone 0, and also increments the read disturb count 302-07 for neighboring block 0, zone 7. In another example, when a read operation is performed on word line 304, located at the edge of block 0, zone 1 that neighbors zone 0 or block 0, the read disturb handling module increments the read disturb count 302-01 for block 1, zone 0, and also increments the read disturb count 302-00 for neighboring block 0, zone 0.

Furthermore, each block of the plurality of non-volatile memory blocks in storage device 120 has one or two neighbors, depending on the physical location of the block in an NVM die 140, 142. For example, block 0 in FIG. 3 has only one neighbor, block 1, while block 1 has two neighbors, block 0 and block 2 (not shown). As a result, a read operation performed on an “edge word line” of a block, such as word lines 0 and 127 in the examples given above, cause the read disturb count to be incremented for both the zone containing the word line and a neighboring zone in a neighboring block, only if there is a block neighboring that edge word line. The term “edge word line” is defined herein to mean a word line at an outer edge of the non-volatile memory block in which the word line is located.

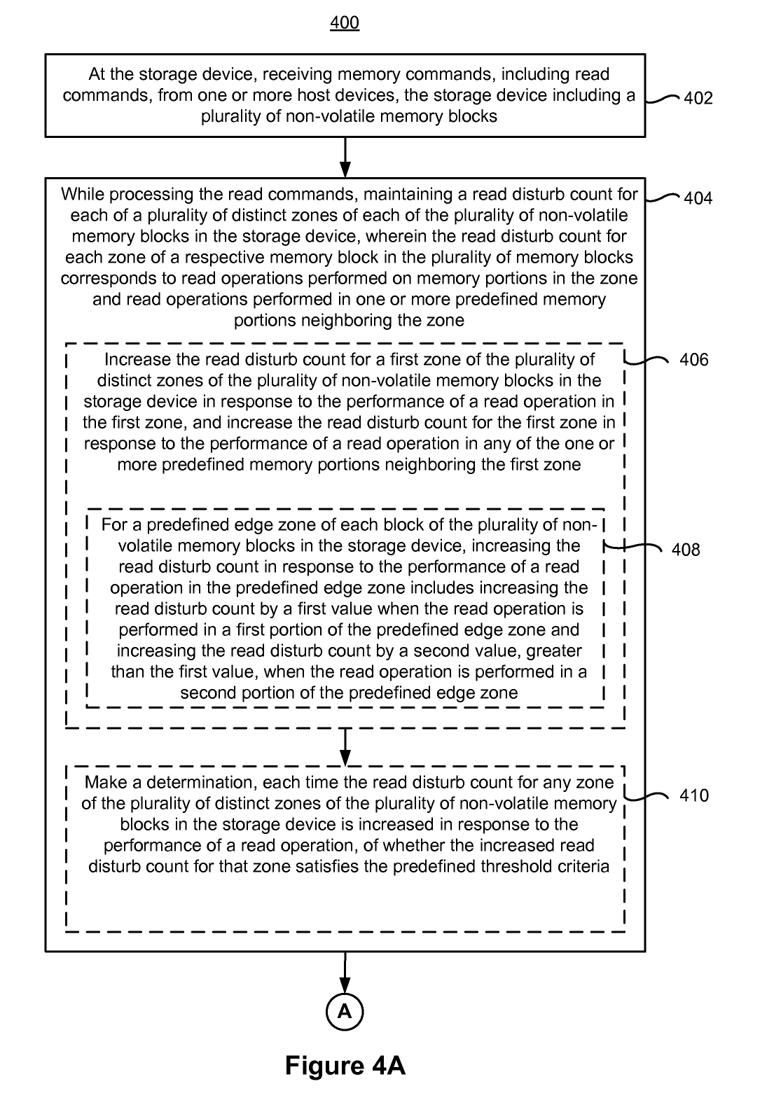

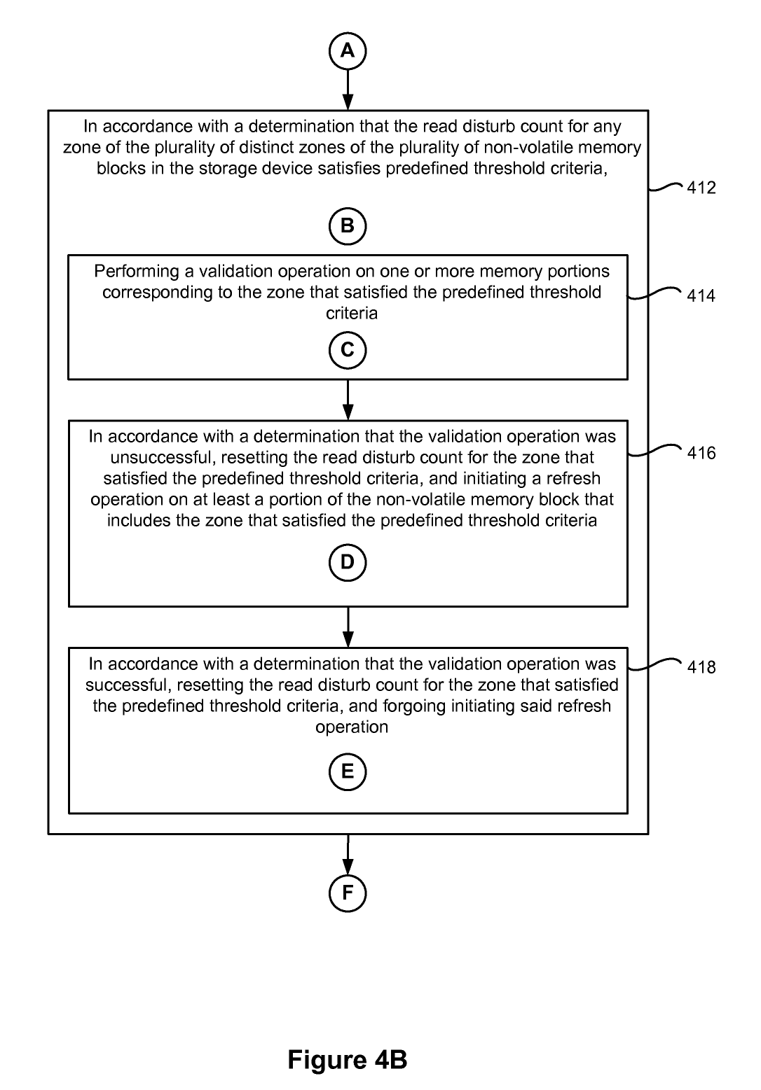

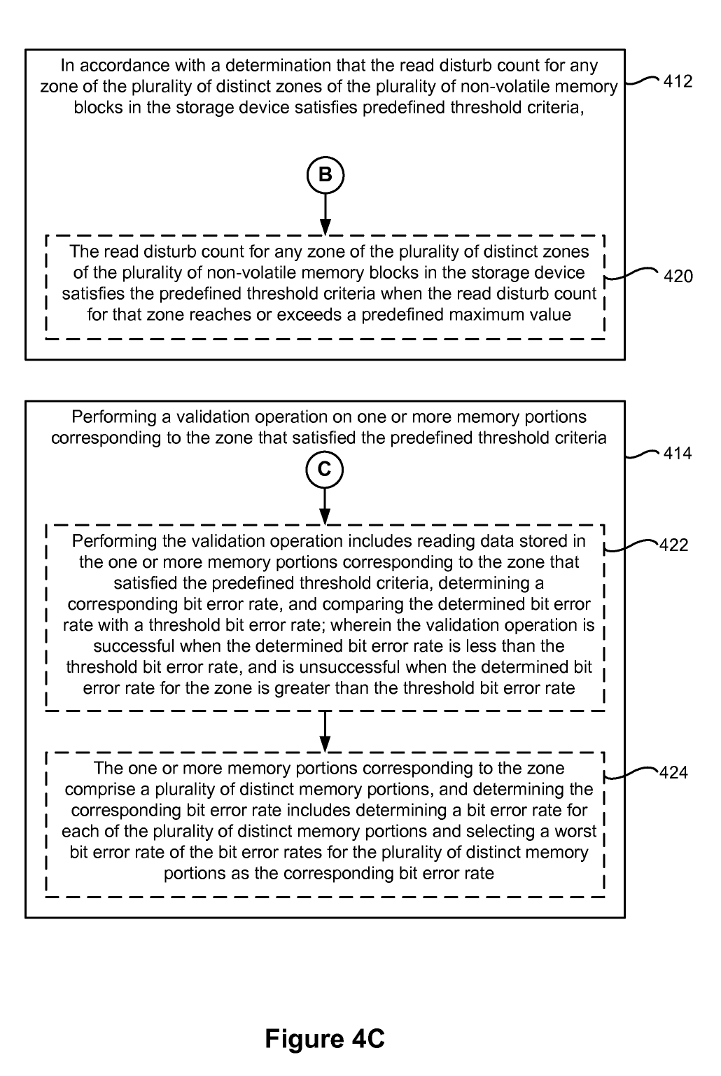

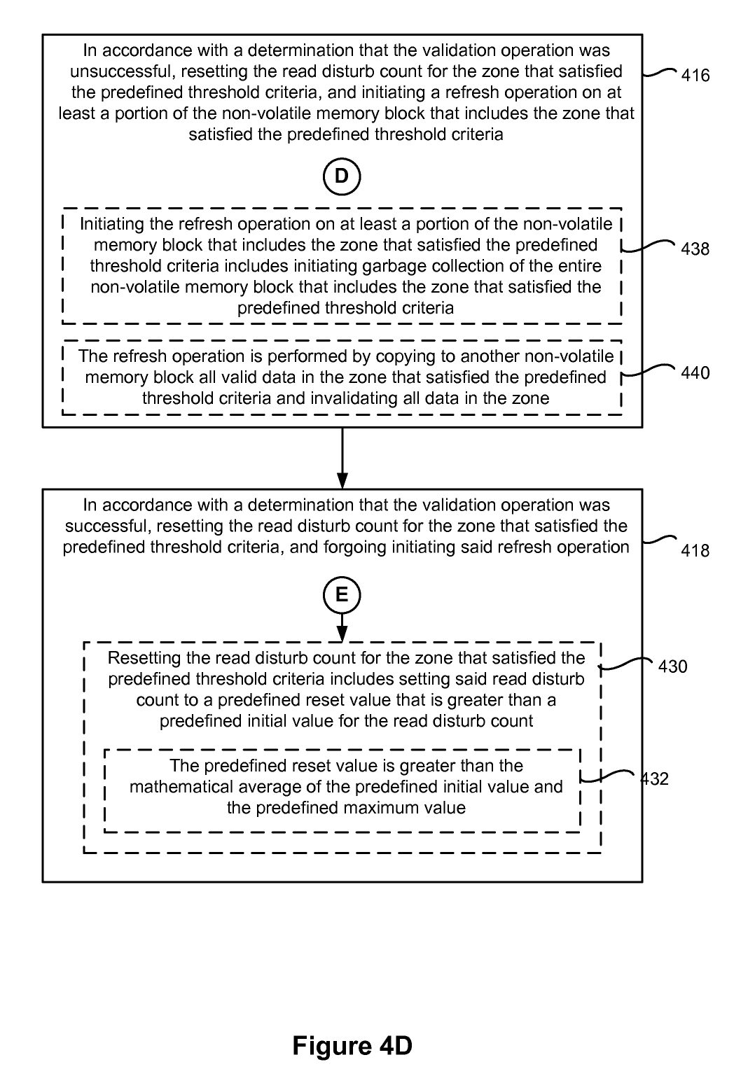

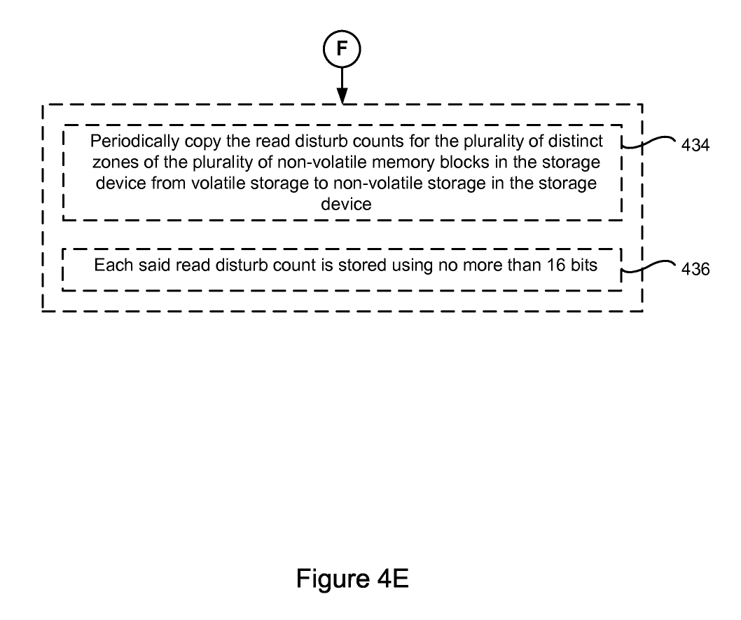

FIGS. 4A-4E illustrate a flowchart diagram of a method of managing a storage system, in accordance with some embodiments. In some embodiments, method 400 is performed by at least in part by a storage device (e.g., storage device 120, FIG. 1) of the storage system (e.g., data storage system 100, FIG. 1) with one or more processors and memory, where the storage device is operatively coupled with a host (e.g., computer system 110, FIG. 1) and the storage device includes one or more memory devices (e.g., NVM devices 140, 142, such as flash memory devices). For example, in some embodiments, method 400 is performed by storage controller 124 (FIG. 1) or a component thereof (e.g., management module 121-1, FIGS. 1-2). In another example, in some embodiments, method 400 is performed by computer system 110 (FIG. 1) or a component thereof (e.g., management module 121-2, FIG. 1). In yet another example, in some embodiments, method 400 is performed by an NVM controller 130 (FIG. 1) or a component thereof (e.g., power throttling logic). In some embodiments, method 400 is governed by instructions that are stored in a non-transitory computer readable storage medium (e.g., memory 206, FIG. 2) and the instructions are executed by one or more processors of the storage device (e.g., CPUs 122, FIGS. 1-2). Optional operations are indicated by dashed lines (e.g., boxes with dashed-line borders).

In method 400, the storage device (device 120, Figure) receives (402) memory commands, including read commands, from one or more host devices (e.g., computer system 110, FIG. 1). The storage device including a plurality of non-volatile memory blocks, as shown in FIG. 3. Further explanation of accessible subunits of a non-volatile memory blocks is provided above.

While processing the read commands, the method includes maintaining (404) a read disturb count for each of a plurality of distinct zones of each of the plurality of non-volatile memory blocks in the storage device, wherein the read disturb count for each zone of a respective memory block in the plurality of memory blocks corresponds to read operations performed on memory portions in the zone and read operations performed in one or more predefined memory portions neighboring the zone. For ease of explanation, it may be assumed that read disturb counts are maintained for all zones of all non-volatile memory blocks in the storage device, but more generally, method 400 maintains read disturb counts for each zones of a plurality of non-volatile memory blocks in the storage device.

In some embodiments, maintaining the read disturb counts (404) includes increasing the read disturb count (406) for a first zone of the plurality of distinct zones of the plurality of non-volatile memory blocks in the storage device, in response to the performance of a read operation in the first zone, and increasing the read disturb count for the first zone in response to the performance of a read operation in any of the one or more predefined memory portions neighboring the first zone. Furthermore, in some embodiments, for a predefined edge zone (e.g., zone 0 or zone 7 of block 1 in FIG. 3) of each block of the plurality of non-volatile memory blocks in the storage device, increasing the read disturb count in response to the performance of a read operation in the predefined edge zone includes increasing the read disturb count by a first value (e.g., 1) when the read operation is performed in a first portion (e.g., any word line other than word line 1 or word line 126 in the example discussed above with reference to FIG. 3) of the predefined edge zone and increasing the read disturb count by a second value (e.g., 2), greater than the first value, when the read operation is performed in a second portion (e.g., word line 1 or word line 126 in the example discussed above with reference to FIG. 3) of the predefined edge zone.

In some embodiments, maintaining the read disturb counts (404) also includes making a determination (410), each time the read disturb count for any zone of the plurality of distinct zones of the plurality of non-volatile memory blocks in the storage device is increased in response to the performance of a read operation, of whether the increased read disturb count satisfies predefined threshold criteria. In some embodiments, the read disturb count for any zone of the plurality of distinct zones of the plurality of non-volatile memory blocks in the storage device satisfies (420) the predefined threshold criteria when the read disturb count for that zone reaches or exceeds a predefined maximum value, such as 65525 or 65535.

Next, method 400 includes performing a set of operations, described next, in accordance with a determination (412) that the read disturb count for any zone of the plurality of distinct zones of the plurality of non-volatile memory blocks in the storage device satisfies the aforementioned predefined threshold criteria. In particular, in accordance with that determination, the method includes performing a validation operation (414) on one or more memory portions corresponding to the zone that satisfied the predefined threshold criteria. In accordance with a determination that the validation operation was unsuccessful, method 400 includes resetting (416) the read disturb count for the zone that satisfied the predefined threshold criteria, and initiating a refresh operation on at least a portion of the non-volatile memory block that includes the zone that satisfied the predefined threshold criteria. Further, in accordance with a determination that the validation operation was successful, the method 400 includes resetting (418) the read disturb count for the zone that satisfied the predefined threshold criteria, and forgoing initiating said refresh operation.

More specifically, in some embodiments, performing the validation operation (414) includes reading (422) data stored in the one or more memory portions corresponding to the zone that satisfied the predefined threshold criteria, determining a corresponding bit error rate, and comparing the determined bit error rate with a threshold bit error rate. The validation operation is successful when the determined bit error rate is less than the threshold bit error rate, and is unsuccessful when the determined bit error rate for the zone is greater than the threshold bit error rate. Furthermore, in some embodiments, the one or more memory portions corresponding to the zone include a plurality of distinct memory portions, and determining the corresponding bit error rate (422) includes determining (424) a bit error rate for each of the plurality of distinct memory portions and selecting a worst bit error rate of the bit error rates for the plurality of distinct memory portions as the corresponding bit error rate. For example, in some embodiments, the validation operation is performed by reading one codeword (or, alternatively, two codewords) from each word line (collectively herein called the sampled codewords) in the zone that satisfied the predefined threshold criteria, decoding those codewords so as to determine a bit error rate (BER) for each of the code words, identifying the worst of those bit error rates as the “determined bit error rate,” and then comparing that worst bit error rate with the threshold bit error rate. The codewords that are read and decoded may be collectively called the sampled codewords.

In some embodiments, initiating (416) a refresh operation on at least a portion of the non-volatile memory block that includes the zone that satisfied the predefined threshold criteria includes initiating garbage collection of the entire non-volatile memory block that includes the zone that satisfied the predefined threshold criteria. Thus, the unsuccessful validation operation is treated as a proxy for the reliability of data stored in the entire corresponding non-volatile memory block. In some embodiments, initiating garbage collection on a particular block is accomplished by passing to a garbage collection module a command to prioritize garbage collection of that particular block. In response, the garbage collection module copies valid data from the particular block to another block (e.g., an un-programmed block, or a block having un-programmed pages to which data can be written, distinct from the non-volatile memory block that includes the zone that satisfied the predefined threshold criteria), and schedules the particular block for erasure.

In some alternative embodiments, the refresh operation (416) is performed by copying to another non-volatile memory block all valid data in the zone that satisfied the predefined threshold criteria and invalidating all data in the zone. More specifically, in some embodiments, only the zone that failed is refreshed when predefined criteria are satisfied, such as when only the one zone of the eight zones in a block has a read disturb count greater than a second threshold (e.g., 32767), and otherwise garbage collection is initiated on the entire block. Alternatively, when no more than two zones of the entire set of zones in a block have a read disturb count greater than the second threshold, a refresh is performed on just the one or two zones having a read disturb count greater than the second threshold, and otherwise garbage collection is initiated on the entire block.

In some embodiments, in accordance with a determination that the validation operation was successful, resetting (418) the read disturb count for the zone that satisfied the predefined threshold criteria includes setting (430) that read disturb count to a predefined reset value that is greater than a predefined initial value for the read disturb count. In some embodiments, the predefined reset value is greater than the mathematical average of the predefined initial value and the predefined maximum value (432). For example, in embodiments in which each read disturb count is stored as a sixteen bit number, and thus has a potential range of 0 to 65535, the read disturb count for a block is initialized to 0 (or alternatively, another relatively low value, such as 10) each time the block is erased. But when the validation operation is successful, the read disturb count for the zone is reset to an intermediate value, such as 49152 (equal to 75 percent of 2¹⁶). Optionally, but typically, the predefined reset value is greater than the mathematical average of the predefined initial value and the predefined maximum value. the predefined reset value is greater than the mathematical average of the predefined initial value and the predefined maximum value

By resetting the read disturb count to the predefined reset value (e.g., the aforementioned intermediate value), the read disturb count for that zone will reach the predefined maximum value after a much smaller number of read disturb events than if the read disturb count were reset to a value of zero. As a result, once a zone has had a sufficient number of read disturb events to trigger a validation operation, and the validation operation is successful, the zone is rechecked more frequently (i.e., after much fewer read disturb events) than the initial zone check rate. In the example above, each zone is initial validated only after approximately 65535 read disturb events, but thereafter is re-validated each time an additional 16384 read disturb events occur. In this way, once a hot spot with respect to read disturb events is identified, the bit error rate of the corresponding zone is rechecked often so that a refresh operation will be performed relatively quickly after the read disturbs cause the bit error rate to rise above a threshold error rate. In some embodiments, the threshold bit error rate is less than the maximum bit error rate for which data can be reliably corrected using the error correction code that is stored with the data in the block.

In some embodiments, method 400 includes periodically copying (434) the read disturb counts (e.g., read disturb counts table 226) for the plurality of distinct zones of the plurality of non-volatile memory blocks in the storage device from volatile storage to non-volatile storage in the storage device. In such embodiments, read disturb counts table 226 is stored in volatile memory, such as DRAM, in management module 121-1 or elsewhere in the storage device, and that table is periodically (e.g., once every N minutes, such as 5 minutes) copied to non-volatile storage (e.g., flash memory) in the storage device. In the event of a power failure or power down, upon the storage device being powered back up, read disturb counts table 226 is initialized from the last-saved copy of read disturb counts table 226 in non-volatile memory.

In some embodiments, each said read disturb count is stored using no more than 16 bits (436). Typically, 16 bits would not be sufficient to maintain a count of read disturbs for an entire block, but because read disturb counts are maintained for each zone of the plurality of storage blocks, and because the read disturb count is reset to an intermediate value when a validation operation on one more memory portions corresponding to the zone is successful, a 16 bit read disturb count value is sufficient to track and handle read disturbs. Furthermore, by limiting the size of each read disturb count to 16 bits, the amount of volatile and non-volatile storage needed to store read disturb counts table 226 is reduced, particularly when compared with read disturb counts stored using 24 or 32 bits per read disturb count.

It should be understood that the particular order in which the operations in FIGS. 4A-4E have been described is merely exemplary and is not intended to indicate that the described order is the only order in which the operations could be performed. One of ordinary skill in the art would recognize various ways to reorder the operations described herein.

It will be understood that, although the terms “first,” “second,” etc. may be used herein to describe various elements, these elements should not be limited by these terms. These terms are only used to distinguish one element from another. For example, a first region could be termed a second region, and, similarly, a second region could be termed a first region, without changing the meaning of the description, so long as all occurrences of the “first region” are renamed consistently and all occurrences of the “second region” are renamed consistently. The first region and the second region are both regions, but they are not the same region.

The terminology used herein is for the purpose of describing particular embodiments only and is not intended to be limiting of the claims. As used in the description of the embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the phrase “at least one of A, B, and C” is to be construed to require one or more of the listed items, and this phase reads on a single instance of A alone, a single instance of B alone, or a single instance of C alone, while also encompassing combinations of the listed items such “one or more of A and one or more of B without any of C,” and the like.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A method of managing a storage device, comprising:
at the storage device, receiving memory commands, including read commands, from one or more host devices, the storage device including a plurality of non-volatile memory blocks;
while processing the read commands, maintaining a read disturb count for each of a plurality of distinct zones of each of the plurality of non-volatile memory blocks in the storage device, wherein the read disturb count for each zone of a respective memory block in the plurality of memory blocks corresponds to read operations performed on memory portions in the zone and read operations performed in one or more predefined memory portions neighboring the zone;
in accordance with a determination that the read disturb count for any zone of the plurality of distinct zones of the plurality of non-volatile memory blocks in the storage device satisfies predefined threshold criteria,
performing a validation operation on one or more memory portions corresponding to the zone that satisfied the predefined threshold criteria;
in accordance with a determination that the validation operation was unsuccessful, resetting the read disturb count for the zone that satisfied the predefined threshold criteria, and initiating a refresh operation on at least a portion of the non-volatile memory block that includes the zone that satisfied the predefined threshold criteria; and
in accordance with a determination that the validation operation was successful, resetting the read disturb count for the zone that satisfied the predefined threshold criteria, and forgoing initiating said refresh operation.

2. The method of claim 1, the method further including making a determination, each time the read disturb count for any zone of the plurality of distinct zones of the plurality of non-volatile memory blocks in the storage device is increased in response to the performance of a read operation, of whether the increased read disturb count satisfies the predefined threshold criteria.

3. The method of claim 1, the method further including:
increasing the read disturb count for a first zone of the plurality of distinct zones of the plurality of non-volatile memory blocks in the storage device in response to the performance of a read operation in the first zone; and
increasing the read disturb count for the first zone in response to the performance of a read operation in any of the one or more predefined memory portions neighboring the first zone.

4. The method of claim 3, wherein, for a predefined edge zone of each block of the plurality of non-volatile memory blocks in the storage device, increasing the read disturb count in response to the performance of a read operation in the predefined edge zone comprises increasing the read disturb count by a first value when the read operation is performed in a first portion of the predefined edge zone and increasing the read disturb count by a second value, greater than the first value, when the read operation is performed in a second portion of the predefined edge zone.

5. The method of claim 1, wherein the read disturb count for any zone of the plurality of distinct zones of the plurality of non-volatile memory blocks in the storage device satisfies the predefined threshold criteria when said read disturb count reaches or exceeds a predefined maximum value.

6. The method of claim 5, wherein resetting the read disturb count for the zone that satisfied the predefined threshold criteria comprises setting said read disturb count to a predefined reset value that is greater than a predefined initial value for the read disturb count.

7. The method of claim 6, wherein the predefined reset value is greater than the mathematical average of the predefined initial value and the predefined maximum value.

8. The method of claim 1, wherein performing the validation operation comprises reading data stored in the one or more memory portions corresponding to the zone that satisfied the predefined threshold criteria, determining a corresponding bit error rate, and comparing the determined bit error rate with a threshold bit error rate; wherein the validation operation is successful when the determined bit error rate is less than the threshold bit error rate, and is unsuccessful when the determined bit error rate for the zone is greater than the threshold bit error rate.

9. The method of claim 8, wherein the one or more memory portions corresponding to the zone comprise a plurality of distinct memory portions, and determining the corresponding bit error rate comprises determining a bit error rate for each of the plurality of distinct memory portions and selecting a worst bit error rate of the bit error rates for the plurality of distinct memory portions as the corresponding bit error rate.

10. The method of claim 1, further including periodically copying the read disturb counts for the plurality of distinct zones of the plurality of non-volatile memory blocks in the storage device from volatile storage to non-volatile storage in the storage device.

11. The method of claim 1, wherein each said read disturb count is stored using no more than 16 bits.

12. The method of claim 1, wherein initiating the refresh operation on at least a portion of the non-volatile memory block that includes the zone that satisfied the predefined threshold criteria comprises initiating garbage collection of the entire non-volatile memory block that includes the zone that satisfied the predefined threshold criteria.

13. The method of claim 1, wherein the refresh operation is performed by copying to another non-volatile memory block all valid data in the zone that satisfied the predefined threshold criteria and invalidating all data in the zone.

14. A storage device, comprising:
non-volatile memory, including a plurality of non-volatile memory blocks; and
one or more storage controllers having one or more processors configured to execute instructions in one or more programs, wherein the one or more storage controllers are configured to perform operations comprising:
at the storage device, receiving memory commands, including read commands, from one or more host devices;
while processing the read commands, maintaining a read disturb count for each of a plurality of distinct zones of each of the plurality of non-volatile memory blocks in the storage device, wherein the read disturb count for each zone of a respective memory block in the plurality of memory blocks corresponds to read operations performed on memory portions in the zone and read operations performed in one or more predefined memory portions neighboring the zone;
in accordance with a determination that the read disturb count for any zone of the plurality of distinct zones of the plurality of non-volatile memory blocks in the storage device satisfies predefined threshold criteria,
performing a validation operation on one or more memory portions corresponding to the zone that satisfied the predefined threshold criteria;
in accordance with a determination that the validation operation was unsuccessful, resetting the read disturb count for the zone that satisfied the predefined threshold criteria, and initiating a refresh operation on at least a portion of the non-volatile memory block that includes the zone that satisfied the predefined threshold criteria; and
in accordance with a determination that the validation operation was successful, resetting the read disturb count for the zone that satisfied the predefined threshold criteria, and forgoing initiating said refresh operation.

15. The storage device of claim 14, wherein the one or more storage controllers include a read disturb module for maintaining the read disturb count for each of the plurality of distinct zones of each of the plurality of non-volatile memory blocks in the storage device, performing the validation operation, and initiating the refresh operation in accordance with a determination that the validation operation was unsuccessful.

16. The storage device of claim 14, wherein the one or more storage controllers are further configured to perform operations comprising:
increasing the read disturb count for a first zone of the plurality of distinct zones of the plurality of non-volatile memory blocks in the storage device in response to the performance of a read operation in the first zone; and
increasing the read disturb count for the first zone in response to the performance of a read operation in any of the one or more predefined memory portions neighboring the first zone.

17. The storage device of claim 14, wherein the read disturb count for any zone of the plurality of distinct zones of the plurality of non-volatile memory blocks in the storage device satisfies the predefined threshold criteria when said read disturb count reaches or exceeds a predefined maximum value.

18. The storage device of claim 14, wherein performing the validation operation comprises reading data stored in the one or more memory portions corresponding to the zone that satisfied the predefined threshold criteria, determining a corresponding bit error rate, and comparing the determined bit error rate with a threshold bit error rate; wherein the validation operation is successful when the determined bit error rate is less than the threshold bit error rate, and is unsuccessful when the determined bit error rate for the zone is greater than the threshold bit error rate.

19. The storage device of claim 14, wherein the one or more storage controllers are further configured to perform operations comprising periodically copying the read disturb counts for the plurality of distinct zones of the plurality of non-volatile memory blocks in the storage device from volatile storage to non-volatile storage in the storage device.

20. A non-transitory computer readable-storage medium, storing one or more programs configured for execution by one or more processors of a storage device, the one or more programs including instructions for:
at the storage device, receiving memory commands, including read commands, from one or more host devices, the storage device including a plurality of non-volatile memory blocks;
while processing the read commands, maintaining a read disturb count for each of a plurality of distinct zones of each of the plurality of non-volatile memory blocks in the storage device, wherein the read disturb count for each zone of a respective memory block in the plurality of memory blocks corresponds to read operations performed on memory portions in the zone and read operations performed in one or more predefined memory portions neighboring the zone;
in accordance with a determination that the read disturb count for any zone of the plurality of distinct zones of the plurality of non-volatile memory blocks in the storage device satisfies predefined threshold criteria,
performing a validation operation on one or more memory portions corresponding to the zone that satisfied the predefined threshold criteria;
in accordance with a determination that the validation operation was unsuccessful, resetting the read disturb count for the zone that satisfied the predefined threshold criteria, and initiating a refresh operation on at least a portion of the non-volatile memory block that includes the zone that satisfied the predefined threshold criteria; and
in accordance with a determination that the validation operation was successful, resetting the read disturb count for the zone that satisfied the predefined threshold criteria, and forgoing initiating said refresh operation.

21. The storage medium of claim 20, the one or more programs further comprising instructions for:
increasing the read disturb count for a first zone of the plurality of distinct zones of the plurality of non-volatile memory blocks in the storage device in response to the performance of a read operation in the first zone; and
increasing the read disturb count for the first zone in response to the performance of a read operation in any of the one or more predefined memory portions neighboring the first zone.

22. The storage medium of claim 20, wherein the read disturb count for any zone of the plurality of distinct zones of the plurality of non-volatile memory blocks in the storage device satisfies the predefined threshold criteria when said read disturb count reaches or exceeds a predefined maximum value.

23. The storage medium of claim 20, wherein performing the validation operation comprises reading data stored in the one or more memory portions corresponding to the zone that satisfied the predefined threshold criteria, determining a corresponding bit error rate, and comparing the determined bit error rate with a threshold bit error rate; wherein the validation operation is successful when the determined bit error rate is less than the threshold bit error rate, and is unsuccessful when the determined bit error rate for the zone is greater than the threshold bit error rate.

24. The storage medium of claim 20, the one or more programs further comprising instructions for periodically copying the read disturb counts for the plurality of distinct zones of the plurality of non-volatile memory blocks in the storage device from volatile storage to non-volatile storage in the storage device.
